(19) United States
(12) Patent Application Publication
(10) Pub. No.: US 2007/0152345 A1
(43) Pub. Date: Jul. 5, 2007

(54) Stacked chip packaging structure

(75) Inventors: Ying-Cheng Wu, Miao-li (TW); Ying-Tang Su, Miao-li (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: ALTUS TECHNOLOGY INC., Miao-li Hsien (TW)

(21) Appl. No.: 11/592,848

(22) Filed: Nov. 3, 2006

(30) Foreign Application Priority Data
Jan. 5, 2006 (CN) 200610032772.9

(51) Int. Cl. H01L 23/52

(52) U.S. Cl. 257/777

(57) ABSTRACT

A stacked chip packaging structure (10) includes a substrate (20), a first chip (40), a second chip (70), and a cover (80). The first chip is mounted on the substrate and is electrically connected with the substrate via a first plurality of wires (50a). The second chip is mounted above the first chip and above the wires connected with the first chip and is electrically connected with the substrate via a second plurality of wires (50b). The cover is mounted above the second chip and the wires connected with the second chip. The mounting of the second chip and the cover in such a manner is facilitated through the use of an adhesive/glue (60a, 60b) that is able to function both as an adherent and as a spacer.

### CROSS-REFERENCE TO RELATED APPLICATIONS

This application is related to a co-pending U.S. patent application (Attorney Docket No. US8604), entitled “DIGITAL CAMERA MODULE USING STACKED CHIP PACKAGE”, by Ying-Cheng Wu et al. Such application has the same assignee as the present application and has been concurrently filed herewith. The above-identified application is incorporated herein by reference.

### TECHNICAL FIELD

The present invention generally relates to integrated circuit chip packaging structures and, more particularly, to a stacked chip packaging structure.

### BACKGROUND

Generally, digital cameras are image-recording media capable of photographing a plurality of still images without using film. Such a digital camera typically uses an image pickup device, which is a kind of semiconductor device, such as a charge coupled device (CCD) or complementary metal oxide semiconductor (CMOS). In the digital camera, an object image formed on the image pickup device through a lens is converted into an electrical signal by the image pickup device, and the electrical signal is stored as a digital signal, e.g., in a mobile phone or personal digital assistant (PDA), in which the digital camera is mounted, or in a “stand-alone” digital still or video camera unit. In order to protect the image pickup device from contamination or pollution (i.e. from dust or water vapor), the image pickup device is generally sealed in a structural package.

Conventional chip packages, however, only allow packaging of one single chip in each package. In the case where a digital camera module having multiple functions is necessary, a peripheral chip, such as a flash memory chip or a digital signal processor (DSP) chip, must be packaged in a single chip package, in accordance with the conventional chip packaging method. Two such chip packages occupy more area in the mobile phone, PDA, or stand-alone camera unit, which accordingly is prone to adversely affect miniaturization thereof.

One way of solving the aforesaid problem is to fabricate more than one chip in a single package. FIG. 6 (related art) shows a typical stacked chip package 90, which includes two chips packaged in a single packaging structure. The package 90 includes a substrate 91, a first chip 93, a second chip 95, a cover 97, and a plurality of wires 98. The substrate 91 includes a board portion 910, a sidewall portion 912, and a receiving cavity 914 formed between the board portion 910 and the sidewall portion 912. Multiple conductive leads 915 are arranged on an upper surface of the board portion 910 and are exposed to the receiving cavity 914. The conductive leads 915 further extend to a bottom surface of the board portion 90, in order to electrically connect the package 90 to external circuitry. The first chip 93 is mounted on the upper surface of the board portion 910 and is received in the receiving cavity 914. The second chip 95 is directly mounted on the top of the first chip 93. Both of the first and second chips 93, 95 have a plurality of conductive points on the upper surfaces thereof. Each wire 98 electrically connects a conductive point of the chips 93, 95 to a corresponding conductive lead 915 of the substrate 91. The cover 97 is fixed to the top of the sidewall portion 912 of the substrate 91 to close the receiving cavity 914.

However, the second chip 95 must be smaller in size than the first chip 93 to allow the conductive points of the first chip 93 to connect to the wires 98. As a result, the package 90 is not unsuitable for an apparatus where an image sensor chip (the second chip), needs to be mounted on the top of a peripheral chip (the first chip) and has a size larger than the size of the peripheral chip.

In addition, the wires 98, which electrically connect the conductive points of the first chip 93 to the leads 915, may be damaged through contact with the second chip 95.

Therefore, an improved stacked chip packaging structure is desired in order to overcome the above-described shortcomings.

### SUMMARY

In one aspect, a stacked chip packaging structure is provided. The stacked chip packaging structure includes a substrate, a first chip, a second chip, and a cover. The first chip is mounted on the substrate and electrically connects with the substrate via a first plurality of wires. The second chip is mounted above the first chip and the first plurality of wires. Further, the second chip is electrically connected with the substrate via a second plurality of wires. The cover is mounted yet above the second chip and the second plurality of wires.

Other advantages and novel features will become more apparent from the following detailed description when taken in conjunction with the accompanying drawings.

### BRIEF DESCRIPTION OF THE DRAWINGS

Many aspects of the present stacked chip packaging structure can be better understood with reference to the following drawings. The components in the drawings are not necessarily drawn to scale, the emphasis instead being placed upon clearly illustrating the principles of the stacked chip packaging structure. Moreover, in the drawings, like reference numerals designate corresponding parts throughout the several views.

FIG. 1 is a schematic, cross-sectional view of a stacked chip packaging structure, according to a first preferred embodiment;

FIG. 2 is a schematic, cross-sectional view of a stacked chip packaging structure, according to a second preferred embodiment;

FIG. 3 is a schematic, cross-sectional view of a stacked chip packaging structure, according to a third preferred embodiment;

FIG. 4 is a schematic, cross-sectional view of a stacked chip packaging structure, according to a fourth preferred embodiment;

FIG. 5 is a schematic, cross-sectional view of a stacked chip packaging structure, according to a fifth preferred embodiment; and

FIG. 6 is a cross-sectional view of a typical stacked chip package.

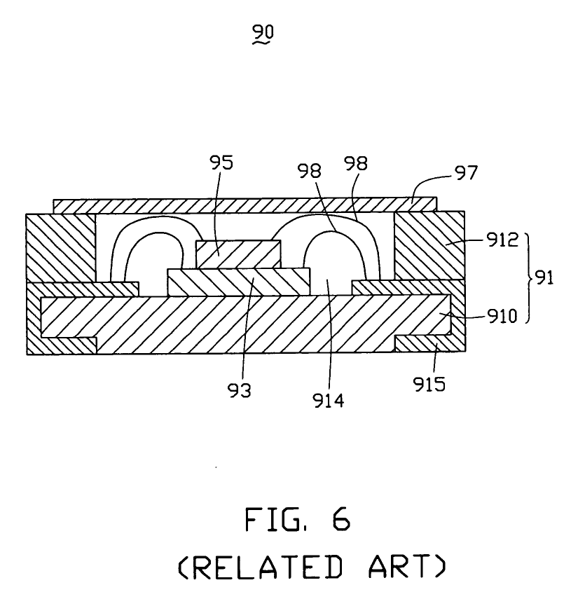

### DETAILED DESCRIPTION OF THE PERFERRED EMBODIMENTS

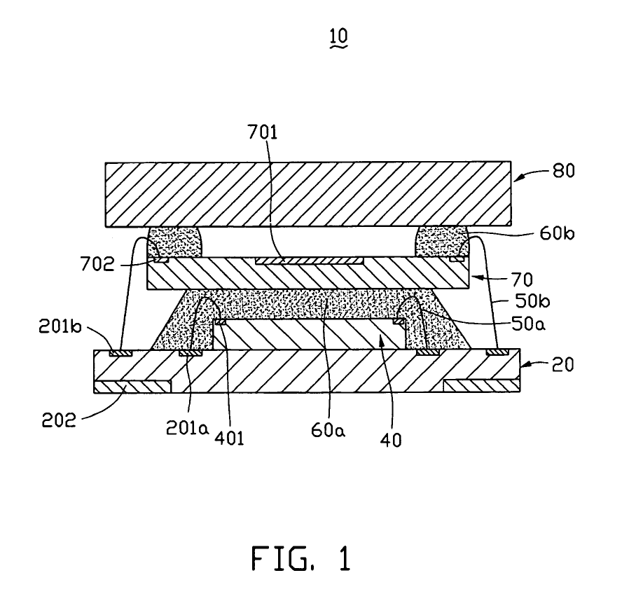

As illustrated in FIG. 1, a stacked chip packaging structure 10, according to a first preferred embodiment, includes a substrate 20; a first chip 40; a first and second plurality of wires 50a, 50b; an adhesive/glue 60a, 60b; a second chip 70; and a cover 80.

The substrate 20 can be, e.g., a ceramic substrate, printed circuit board, flame retardant type 4 (FR4) substrate, or the like. In the first preferred embodiment, the substrate 20 has a single-layer structure. The substrate 20 has a plurality of first top contacts 201a and a plurality of second top contacts 201b directly on an upper surface thereof and further has a plurality of bottom contacts 202 directly on a bottom surface, the bottom surface being positioned opposite to the upper surface. The first and second top contacts 201a, 201b are arranged around/proximate a circumference/perimeter of the upper surface. In particular, the second top contacts 201b are disposed directly on a peripheral portion of the upper surface, and the first top contacts 201a are disposed inside the second top contacts 201b, directly on the upper surface. Each bottom contact 202 is electrically attached/linked to a corresponding top contact 201a, 201b, via a corresponding connecting device, such as conductive through hole, conductive lead, or the like. The bottom contacts 202 are arranged in such a pattern that they match/mate with and electrically connect/link to external circuitry.

The first chip 40 can, for example, be a peripheral chip chosen from the group consisting of flash memory chips, drive chips, digital signal processor (DSP) chips, and the like. The first chip 40 is mounted on the substrate 20, surrounded by the first and second top contacts 201a, 201b. A plurality of first pads 401 is arranged on an upper surface of the first chip 40. Each first pad 401 is electrically connected/joined to a corresponding first top contact 201a via a corresponding wire 50a.

The adhesive/glue 60a is applied to an outer periphery (i.e., adjacent the side surfaces thereof) and the upper surface of the first chip 40. The adhesive/glue 60a is configured to ensure a spacing between the first chip 40 and the second chip 70 is maintained and, in particular, to hold the second chip 70 above each wire loop formed by the wires 50a (i.e., the adhesive/glue 60a functions as both an adherent and a spacer). In order to protect the wires 50a from the second chip 70 and/or damage by external force, the adhesive/glue 60a can be further applied to cover the wires 50a. The adhesive/glue 60a can be somewhat viscous and flowing when initially applied and must be able to be hardened, e.g., by self-curing, heating, or application of ultraviolet light.

The second chip 70 can be, for example, an image sensor chip and is adhered/attached on top of the first chip 40 via the adhesive/glue 60a. The second chip 70 has an active area 701 (e.g., a photo-registering zone) and a plurality of second pads 702 arranged around the active area 701, on an upper surface thereof. Each second pad 702 is electrically connected/linked to a corresponding second contact 201b of the substrate 20, via a corresponding wire 50b.

The adhesive/glue 60b is advantageously applied to a periphery of the upper surface of the second chip 70 around the active area 701, the adhesive/glue 60b and the cover 80 thereby serving to seal and protect the active area 701. The adhesive/glue 60b is configured to hold/space the cover 80 above each wire loop formed by the wires 50b. In order to protect the wires 50b from damage due to external force, the adhesive/glue 60b can be further applied to the wires 60b to cover the whole of each wire 60b.

The cover 80 is stacked above the second chip 70 and is adhered/attached to the adhesive/glue 60b, thereby permanently mounting the cover 80 relative to the second chip 70. The cover 80 and the adhesive/glue 60b cooperatively close the active area 701 of the second chip 70, thereby protecting the active area 701 from pollution/contamination and/or other external environmental effects (e.g., temperature extremes, humidity, etc.). The cover 80 is advantageously transparent, thus permitting light to pass therethrough to the active area 701 of the second chip 70.

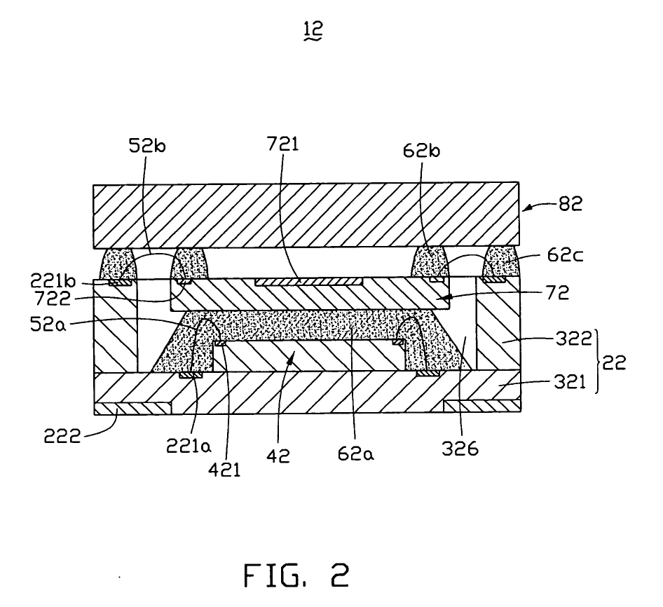

FIG. 2 shows a stacked chip packaging structure 12, according to a second preferred embodiment. The packaging structure 12 is similar to the packaging structure 10 and is constructed to include a substrate 22; a first chip 42; a plurality of wires 52a, 52b; an adhesive/glue 62a, 62b; a second chip 72; and a cover 82. The substrate 22 includes a plurality of first and second top contacts 221a, 221b, a plurality of bottom contacts 222. The first chip 42 includes a plurality of first pads 421. The second chip 72 includes an active area 721 and a plurality of second pads 722. The packaging structure 12 is different from the packaging structure 10, primarily in the structure of the substrate 22 and mounting of the cover 82.

The substrate 22 has a two-layered structure, that is to say, the substrate 22 includes a board portion 321 and a frame portion 322 disposed on the board portion 321. The board portion 321 and frame portion 322 cooperatively define a receiving cavity 326 therebetween. The first top contacts 221a are disposed on an upper surface of the board portion 321 and are contained in the receiving cavity 326. The second top contacts 221b are arranged on an upper surface of the frame portion 311.

The first chip 42 is mounted on the board portion 321, surrounded by the first top pads 221a, and received in the receiving cavity 326. The first chip pads 421 are electrically connected/linked with the first top contacts 221a via the wires 52a.

The second chip 72 is fixed on top of the first chip 42 by the adhesive/glue 62a, which is applied to both the top and periphery of the first chip 42 and holds/spaces the second chip 72 above each wire loop formed by the wires 52a. Each second pad 722 is electrically connected with a corresponding second top pad 221b, via a corresponding wire 52b.

The cover 82 is fixed on top of second chip 72 by the adhesive/glue 62b, which is applied to the upper periphery of the second chip 72 and has a height extending above each wire loop formed by the wires 52b, thus ensuring the needed spacing between the second chip 72 and the cover 82. Moreover, the cover 82 is further adhered/attached to the frame portion 322 via another adhesive/glue 62c, which is applied to the top of the frame portion 322, and holds the cover 82 above each wire loop formed by the wires 52b. In order to protect the wires 52b from damage due to external forces, one of the adhesive/glue 62b and 62c can be further applied to the wires 52b to cover the whole of each wire 52b.

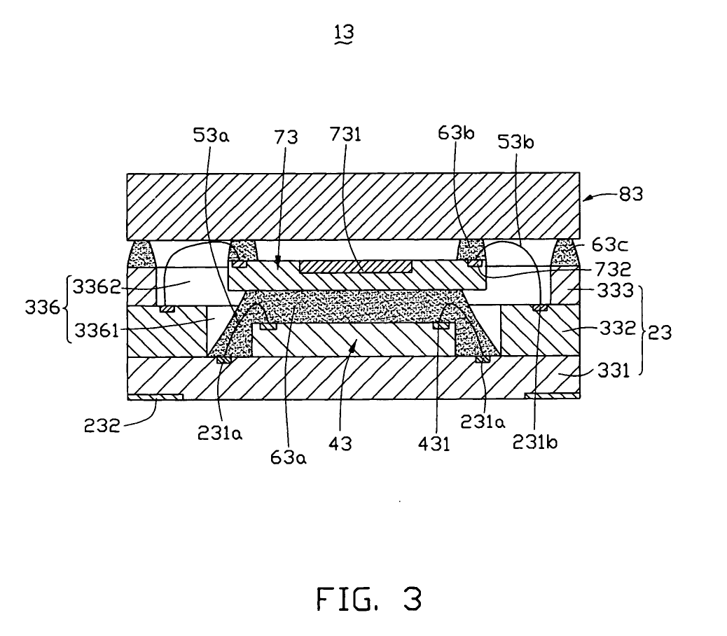

FIG. 3 shows a stacked chip packaging structure 13, according to a third preferred embodiment. The packaging structure 13 is similar to the packaging structure 10 and is constructed to include a substrate 23; a first chip 43; a plurality of wires 53a, 53b; an adhesive/glue 63a, 63b; a second chip 73; and a cover 83. The substrate 23 includes a plurality of first and second top contacts 231a, 231b; and a plurality of bottom contacts 232. The first chip 43 includes a plurality of first pads 431. The second chip 73 includes an active area 731 and a plurality of second pads 732. The packaging structure 13 is different from the packaging structure 10 mainly in the structure of the substrate 23 and the mounting of the cover 83.

The substrate 23 has a three-layered structure, that is to say, the substrate 23 includes a board portion 331, a first frame portion 332, and a second frame portion 333. The first frame portion 332 is disposed on the board portion 331. The second frame portion 333 is provided on an outer periphery of an upper surface of the first frame portion 332. The board portion 331, the first frame portion 332, and a second frame portion 333 cooperatively define a receiving cavity 336 therein. The receiving cavity 336 includes a first cavity 3361 surrounded by the first frame portion 332 and includes a second cavity portion 3362 surrounded by the second frame portion 333. The first top contacts 231a are positioned on an upper surface of the board portion 331 and are exposed to the air/ambient environment. The second top contacts 231b are arranged on an inner periphery of the upper surface of the first frame portion 332 and are also exposed to the air/ambient environment.

The first chip 43 is mounted on the board portion 331, surrounded by the first top pads 231a, and received in the first cavity 3361. The first chip pads 431 are electrically connected with the first top contacts 231a via the wires 53a.

The second chip 73 is mounted on top of the first chip 43 via the adhesive/glue 63a, which is applied to the top and periphery of the first chip 43 and holds/spaces the second chip 73 above each wire loop formed by the wires 53a. Each second pad 732 is respectively electrically connected with a corresponding second top pad 231b, via a corresponding wire 53b.

The cover 83 is mounted on top of the second chip 73 via the adhesive/glue 63b, which is applied to the upper periphery of the second chip 73 and holds the cover 83 above each wire loop formed by the wires 53b, separating the cover 83 from the wire loops associated with the wires 53b. Moreover, the cover 83 is further adhered to the second frame portion 333 via another adhesive/glue 63c, which is applied to the top of the second frame portion 333. In order to protect the wires 53b from damage of external force, at least one of the adhesive/glues 63b and 63c can be further applied to the wires 53b in a manner so as to cover the whole of each wire 53b.

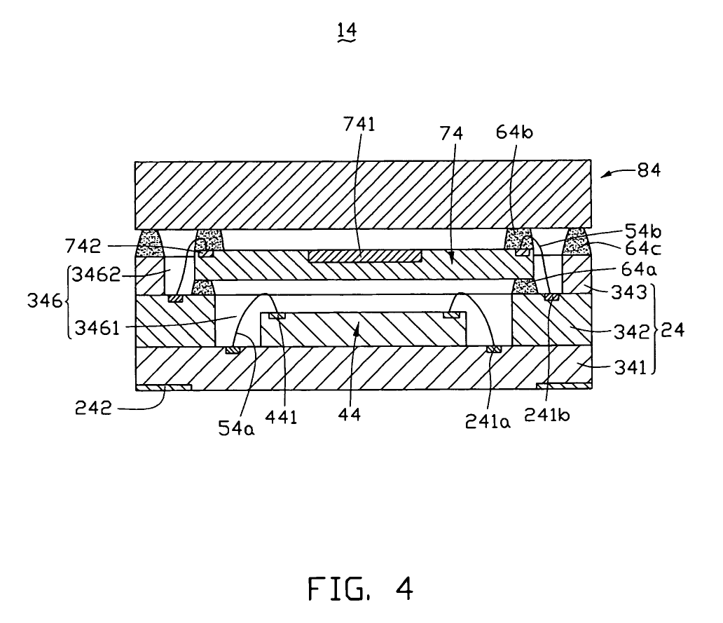

Regarding FIG. 4, a stacked chip packaging structure 14, in accordance with a fourth preferred embodiment, is shown. The packaging structure 14 has a structure similar to that of the packaging structure 13 and includes a triple-layered structure substrate 24; a first chip 44; a plurality of wires 54a, 54b; adhesive/glues 64a, 64b, 64c; a second chip 74; and a cover 84. The substrate 24 includes a board portion 341 provided with a plurality of first top contacts 241a and a plurality of bottom contacts 242, a first frame portion 342 having a plurality of second top contacts 241b, and a second frame portion 343. The first chip 44 includes a plurality of first pads 441. The second chip 74 includes an active area 741 and a plurality of second pads 742. The packaging structure 14 is different from the packaging structure 13 mainly in the way the second chip 74 is mounted.

The second chip 74 of the packaging structure 14 is adhered to the first frame portion 342 via the adhesive/glue 64a, which is applied to an inner periphery of an upper surface of the first frame portion 342. The adhesive/glue 64a holds/spaces the second chip 74 above each wire loop formed by the wires 54a.

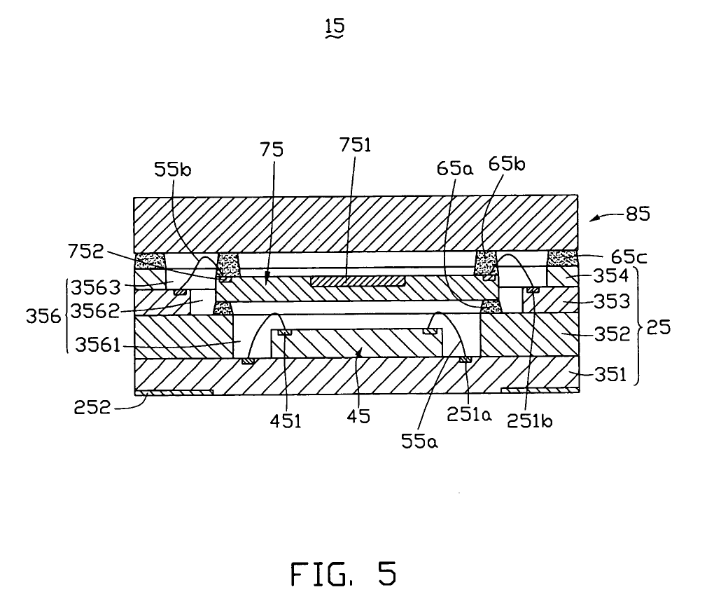

Regarding FIG. 5, a stacked chip packaging structure 15, in accordance with a fifth preferred embodiment, is shown. The packaging structure 15 has a structure similar to that of the packaging structure 14 and includes a substrate 25; a first chip 45; a plurality of wires 55a, 55b; an adhesive/glue 65a, 65b, 65c; a second chip 75; and a cover 85. The first chip 45 includes a plurality of first pads 451. The second chip 75 includes an active area 751 and a plurality of second pads 752. The packaging structure 15 is different from the packaging structure 14 primarily in structure of the substrate 25 and in the mounting of the cover 85.

The substrate 25 of the packaging structure 15 has a four-layered structure and includes a board portion 351, a first frame portion 352, a second frame portion 353, and a third frame portion 354 arranged in that order, bottom-to-top. The board portion 351 and the first, second and third frame portions 351, 352, 353 cooperatively define a receiving cavity 356 therein. The receiving cavity 356 includes a first cavity 3561 surrounded by the first frame portion 352, a second cavity 3562 surrounded by the second frame portion 353, and a third cavity 3563 surrounded by the third frame portion 354. A plurality of first top contacts 251a and a plurality of bottom contacts 252 are arranged on two opposite surfaces of the board portion 351, with the first top contacts 251a being exposed to the first cavity 3561. A plurality of second top contacts is arranged on an upper surface of the second frame portion 353 and are, in turn, exposed to the third cavity 3563.

The cover 85 of the packaging structure 15 is affixed to the second chip 75 via the adhesive/glue 65b. Moreover, the cover 85 is further adhered to the third frame portion 354 via the adhesive/glue 65c, which is applied to the top of the third frame portion 354.

It is to be understood that, in the packaging structures 13, 14, and 15, the first top contacts 231a, 241a, 251a can alternatively be arranged on the top of the first frame portion 332, 342, 352, respectively, and the second top contacts 231b, 241b, 251b can alternatively be arranged on the top of the second frame portion 333, 343, 353, respectively. Further, like in the first embodiment, unless otherwise expressed, any of the various contacts 231, 241, 251 are considered as having been directly formed upon the respective surface with which they are associated. Also, all wires 50-54 have, advantageously, been directly attached to their respective desired locations, via any known wire bonding method, including both direct bonding and soldering methods.

In the aforesaid packaging structures, as the bottom surface of the second chip is spaced above the wires connecting the first chip to the substrate, the size of the second chip can thus be either larger or smaller than that of the first chip. Accordingly, it would facilitate the fabrication of packaging structures using chips having almost any size, within general package processing constraints (e.g., any limitations on individual component size; relative sizing of components to permit desired environmental sealing; etc.).

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A stacked chip packaging structure, comprising:
a substrate including a plurality of top contacts arranged thereon;
a first chip attached to the substrate, the first chip comprising a plurality of first pads disposed on an upper surface thereof;
a second chip disposed above the first chip, the second chip comprising a bottom surface facing the first chip and an upper surface provided with a plurality of second pads thereon;
a plurality of wires electrically respectively connecting one of the first and second contacts to a corresponding top contact of the substrate, each wire forming a wire loop; and
a cover disposed above the second chip, the cover having a bottom surface facing the second chip;
wherein the bottom surface of the second chip is above the wire loops of the wires connected with the first chip, and the bottom surface of the cover is above the wire loops of the wires connected with the second chip.

2. The stacked chip packaging structure as claimed in claim 1, further comprising an adhesive applied to the upper surface of the first chip and to a periphery of an upper surface of the second chip, wherein the adhesive applied to the first chip holds and thereby spaces the second chip above the wire loops of the wires connected with the first chip, the adhesive applied to the first chip fixing the bottom surface of the second chip thereto, the adhesive applied to the second chip holding the cover above the wire loops of the wires connected with the second chip, the adhesive applied to the second chip fixing the bottom surface of the cover thereto.

3. The stacked chip packaging structure as claimed in claim 2, wherein the adhesive is further applied to the wires in a manner so as to cover the whole of each wire.

4. The stacked chip packaging structure as claimed in claim 1, wherein the substrate comprises a board portion and a frame portion attached to the board portion, and the board portion and the frame portion cooperatively define a receiving cavity therein to respectively receive the first and second chips therein.

5. The stacked chip packaging structure as claimed in claim 4, wherein the top contacts includes a plurality of first top contacts and a plurality of second top contacts, the first top contacts are arranged on the board portion and exposed to the cavity and are respectively electrically connected with corresponding first pads of the first chip, and the second top contacts are arranged on the frame portion and respectively electrically connect with corresponding second pads of the second chip.

6. The stacked chip packaging structure as claimed in claim 1, wherein the substrate comprises a board portion, a first frame portion, and a second frame portion arranged in that order, bottom-to-top, and the board portion and the first and second frame portions cooperatively define a receiving cavity therein to receive the first and second chips therein.

7. The stacked chip packaging structure as claimed in claim 6, further comprising an adhesive, wherein the adhesive is applied to at least one of the upper surface of the first chip and an inner periphery of an upper surface of the first frame portion to fix the second chip thereon, and the adhesive holds and thereby spaces the second chip above the wire loops of the wires connected with the first chip.

8. The stacked chip packaging structure as claimed in claim 7, wherein the adhesive is further applied to a periphery of the second chip and holds the cover above the wire loops of the wires connecting with the second chip.

9. The stacked chip packaging structure as claimed in claim 8, wherein the adhesive is further applied to the wires in a manner so as to cover the whole of each wire.

10. The stacked chip packaging structure as claimed in claim 8, wherein the adhesive is further applied to the top of the second frame portion to fix the bottom surface of the cover thereto.

11. The stacked chip packaging structure as claimed in claim 8, wherein the substrate further comprises a third frame portion, the third frame portion is attached to the second frame portion, and the adhesive is further applied to the top of the third frame portion to fix the bottom surface of the cover thereto.

12. The stacked chip packaging structure as claimed in claim 6, wherein the top contacts comprises a plurality of first top contacts and a plurality of second top contacts, the first top contacts are arranged on at least one of the board portion and the first frame portion and are electrically connected with the first pads of the first chip, and the second top contacts are arranged on at least one of the first frame portion and the second frame portion and are electrically connected with the second pads of the second chip.

13. A stacked chip packaging structure, comprising:
a substrate;
a first chip mounted on the substrate, the first chip being electrically connected with the substrate via a first plurality of wires;
a second chip mounted above the first chip and the wires connected with the first chip, the second chip being electrically connected with the substrate via a second plurality of wires; and
a cover mounted above the second chip and the wires connected with the second chip.

14. The stacked chip packaging structure as claimed in claim 13, wherein an adhesive is used to achieve at least one of the mounting of the second chip above the first chip and the mounting of the cover above the second chip, the adhesive being configured to act as a spacer.
